(19) United States
(12) Patent Application Publication
(10) Pub. No.: US 2013/0058154 A1
(43) Pub. Date: Mar. 7, 2013

(54) SEMICONDUCTOR DEVICE AND METHOD OF MANUFACTURING THE SAME

(71) Applicants: Satoshi KATAGIRI, Tokyo (JP); Kenji MAE, Tokyo (JP)

(72) Inventors: Satoshi KATAGIRI, Tokyo (JP); Kenji MAE, Tokyo (JP)

(73) Assignee: Elpida Memory, Inc.

(21) Appl. No.: 13/602,544

(22) Filed: Sep. 4, 2012

(30) Foreign Application Priority Data
Sep. 5, 2011 (JP) 2011-192258

(51) Int. Cl. G11C 11/00

(52) U.S. Cl. 365/148

(57) ABSTRACT

A semiconductor device includes a plurality of first memory cells, at least one of second memory cells, and a control circuit. The plurality of first memory cells are accessed during normal operation, wherein the first memory cell includes a first variable resistance element. The second memory cell is not accessed during the normal operation but accessed at a time of test operation. The second memory cell includes a second variable resistance element practically identical to the first variable resistance element. The control circuit performs forming on the second memory cell at the time of the test operation.

### REFERENCE TO RELATED APPLICATION

This application is based upon and claims the benefit of the priority of Japanese patent application No. 2011-192258, filed on Sep. 5, 2011, the disclosure of which is incorporated herein in its entirety by reference thereto.

### TECHNICAL FIELD

The present invention relates to a semiconductor device and a method of manufacturing the same. In particular, the present invention relates to a semiconductor device including a variable resistance element as a storage element, and a method of performing a forming for acquiring forming condition on the variable resistance element in a manufacturing process of the semiconductor device.

### BACKGROUND

As a present-day semiconductor memory device of large capacity, a DRAM is most popular, and is extensively used in such as a computer system. As a non-volatile semiconductor memory device, on the other hand, a flash memory is extensively used. However, the DRAMs or the flash memories, which now are mainstream devices, are said to be reaching the limit of miniaturization in several years. Hence, investigations into a variety of large-capacity semiconductor memory devices, capable of taking the place of the DRAMs or flash memories, are now going on. In particular, variable resistance elements (RRAM or RERAM) that exploit the phenomenon in which changes in resistance are produced by applying a voltage to transition metal oxides, such as perovskite oxides and NiO, become the center of the attention. Since the variable resistance elements maintain their resistance-changed states even after power down, the variable resistance elements may operate as non-volatile memories.

In writing data in a variable resistance element, two different sorts of write are needed. One is a write of changing a high resistance state to a low resistance state. The other is a write of changing a low resistance state to a high resistance state. In explanations below, the write for changing a high resistance state to a low resistance state is referred to as SET write (hereinafter also referred to as Set), and the write for changing a low resistance state to a high resistance state is referred to as RESET write (hereinafter also referred to as Reset).

The operations of SET write and RESET write may be classified into a unipolar type and a bipolar type. In the unipolar operation, the write is executed as the voltage is applied to the variable resistance element in the same direction for Set and Reset. In the bipolar operation, the write is executed as the voltage is applied to the variable resistance element in opposite directions for Set and Reset. By referring to FIG. 14, the write operation of the bipolar type will now be described. FIG. 14 plots a voltage applied across the electrodes of the variable resistance element as the abscissa, and a current value flowing between both ends at this time as the ordinate. It is assumed that the variable resistance element is initially in a reset state. This state is a high resistance state. If, in this reset state, a positive voltage VDSET is applied across both terminals of the variable resistance element (point A in FIG. 14), the variable resistance element is set to a low resistance state from the high resistance state (transition from point A to point B of FIG. 14). The maximum current flowing at this time is denoted by ICOMP.

On the other hand, if the write is from the Set state to the Reset state, a voltage is applied to in a reverse direction of the write to the Set state. That is to say, a voltage VDRST is applied to the variable resistance element in an opposite direction of that for Set (point C of FIG. 14). The current flowing at this time is denoted by IRST. This resets the variable resistance element from the Set state so that the variable resistance element reverts to the state with large resistance (transition from a point C to a point D in FIG. 14). In reading out from the resistance element, it is determined whether the resistance element is in a Set state or in a Reset state by checking the current flowing when a voltage lower than VDSET is applied to the resistance element.

Meanwhile, a variable resistance element is in an isolated state at the initial state after manufacture, and in order to convert it to a state in which it can be switched between a high resistance state and a low resistance state, it is necessary to form a filament path in the internal by applying a predetermined voltage to a variable resistance element after manufacture. Such a process to form a filament path is referred to as a forming. After the forming, i.e., in the state in which forming is established, the variable resistance element can be stably switched between a high resistance state and a low resistance state, which makes it possible to perform a stable memory operation.

Forming conditions for the forming include such as an applied voltage and an applied time to a variable resistance element. And if a voltage is applied as voltage pulses, pulse number is included in the forming conditions. An appropriate forming condition for variable resistance elements depends on such as manufacturing process of a semiconductor device, film thickness of variable resistance elements, unevenness among lots at the time of manufacture, chip position in a wafer surface, and position in a chip, so the appropriate forming condition is not constant. In order to solve above-mentioned unevenness problem and always perform an optimum forming, for example, in a case where there is unevenness about film thickness of variable resistance element, if the film thickness is thick, a high voltage has to be applied, or the applied time has to be longer (or pulse number has to be increased); whereas if the film thickness is thin, a low voltage has to be applied, or the applied time has to be shorter (or pulse number has to be decreased).

As a phenomenon occurring if a forming is not performed by an appropriate forming condition, for example, if applied voltage is too high, a defect occurs in some cases that it is impossible to revert to a high resistance state after transiting to a low resistance state, which is referred to as over-forming. Or, a difference of resistance between a low resistance state and a high resistance state tends to be small, so that in some cases, an enough margin for reading out cannot be obtained at the time of memory operation.

As seen in the above, it is important to perform the forming under an appropriate forming condition in order to operate stably as a memory using memory cells including variable resistance elements even though there are various types of unevenness. Conventionally, in order to overcome various types of unevenness, an optimum forming condition is searched for by changing the forming condition(s) in a wafer state, so that setting value for the wafer test is determined. This is referred to as (a forming for) “acquiring forming condition” (or forming test).

And as another concern of forming, it is important to complete a forming in a short time from the view point of mass production aptitude of a product. For example, Patent Literature 1 discloses a method comprising a plurality of steps: an initial forming step, a forming step, and a forming resistance value minimizing step in which the forming is completed in a short time.

### [Patent Literature 1]:

JP Patent Kokai Publication No. JP-P2008-210441A

### SUMMARY

The disclosures of the above cited Patent Literature is incorporated herein in their entirety by reference thereto. The analysis below will be presented in the view point of the present invention.

However, as mentioned above, if a forming for acquiring forming condition is performed using some memory cells, there is problem in which a memory cell that has been performed by an inappropriate forming condition becomes a defective cell after the forming for acquiring forming condition. For example, a memory cell that has been in an over-forming state due to high applied voltage becomes a defective cell. The memory cell that becomes a defective cell cannot normally operate as a memory.

Patent Literature 1 describes a technology in which a forming can be performed in a short time, but does not disclose a forming for acquiring forming condition.

Thus, in a semiconductor device comprising memory cells that include variable resistance elements, there is a task to be solved in order to stably operate the semiconductor device as a memory by the following steps: determining an appropriate forming condition by performing a forming for acquiring forming condition; after that performing a forming by the acquired forming condition. Thus there is much to be desired in the art.

In a first aspect of the present disclosure, there is provided a semiconductor device. The semiconductor device comprises: a plurality of first memory cells that are accessed during normal operation, wherein each of the first memory cells includes a first variable resistance element; and at least one second memory cell that is not accessed during the normal operation but accessed at a time of test operation, wherein the at least one second memory cell includes a second variable resistance element practically identical to the first variable resistance element. The semiconductor device further comprises a control circuit that performs forming on the at least one second memory cell at the time of the test operation.

In a second aspect of the present disclosure, there is provided a method of manufacturing a semiconductor device. The semiconductor device includes first variable resistance memory cells that operate as a memory during normal operation and a plurality of second variable resistance memory cells that are used for a forming for acquiring forming condition. The method comprises: performing a forming control for the plurality of second variable resistance memory cells by different conditions from each other; and detecting whether or not each of the plurality of second variable resistance memory cells transits to a first resistance state after the forming control. The method further comprises performing a forming control for the first variable resistance memory cells based on a condition of one(s) among the plurality of second variable resistance memory cells that transits to the first resistance state as a result of the detection.

In a third aspect of the present disclosure, there is provided a system. The system comprises: a semiconductor device and a controller. The semiconductor device includes: a first memory circuit including a plurality of normal and redundancy memory cells each including a variable resistance element; and a second memory circuit including at least one test memory cell including the variable resistance element. And the controller is coupled to the semiconductor device, and is configured to perform a read/write operation on the first memory circuit of the semiconductor device and not to perform the read/write operation on the second memory circuit.

According to the first aspect of the present disclosure, there is provided a semiconductor device in which defective cells are not produced due to a forming for acquiring forming condition in memory cells that operate as a memory at the time of normal operation.

According to the second aspect of the present disclosure, there is provided a method for manufacturing a semiconductor device in which defective cells due to a forming for acquiring forming condition are not produced in memory cells that operates as a memory at the time of normal operation.

### BRIEF DESCRIPTION OF THE DRAWINGS

FIG. 1 is a block diagram of a semiconductor device in accordance with each exemplary embodiment of the present disclosure.

FIG. 2 is a figure showing a connection between the semiconductor device and a tester in accordance with each exemplary embodiment of the present disclosure.

FIG. 3 is a figure showing a connection between the semiconductor device and a controller in accordance with each exemplary embodiment of the present disclosure.

FIG. 4 is a circuit diagram showing a forming voltage measurement circuit of a semiconductor device in accordance with a first exemplary embodiment of the present disclosure.

FIG. 5 is a waveform chart showing an operation of the forming voltage measurement circuit of the semiconductor device in accordance with the first exemplary embodiment.

FIG. 6A is an illustration showing an example of arrangement of second memory cells of the semiconductor device in accordance with the first exemplary embodiment; FIG. 6B shows a memory cell mat in accordance with the first exemplary embodiment.

FIG. 7 is a block diagram showing a configuration of a read/write amplifier of the semiconductor device in accordance with the first exemplary embodiment.

FIG. 8 is a flowchart showing a method of manufacturing the semiconductor device in accordance with the first exemplary embodiment.

FIG. 9 shows a flowchart showing a method of manufacturing the semiconductor device in accordance with the first exemplary embodiment.

FIG. 10 shows a flowchart showing a method of manufacturing the semiconductor device in accordance with the first exemplary embodiment.

FIG. 11 shows a flowchart showing a method of manufacturing the semiconductor device in accordance with the first exemplary embodiment.

FIG. 12 is an illustration showing an example of arrangement of memory cells of a semiconductor device in accordance with a second exemplary embodiment of the present disclosure.

FIG. 13 is a block diagram of a row decoder and a redundant row decoder in the semiconductor device in accordance with the second exemplary embodiment.

FIG. 14 is a figure illustrating an operation of a variable resistance element.

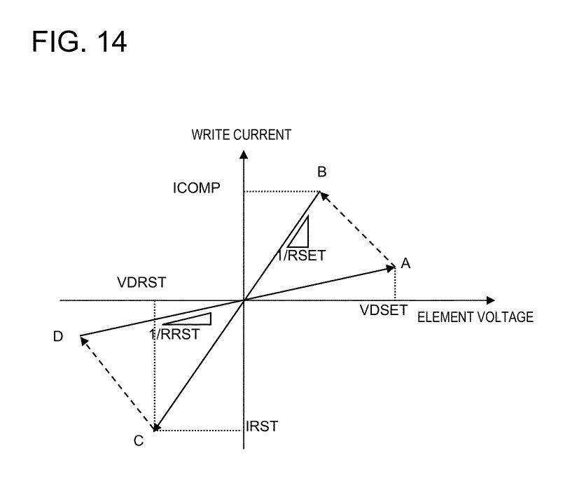

### PREFERRED MODES

An outline of preferred modes of the present disclosure will be described by referring to the drawings as needed. Meanwhile, drawings and drawing reference symbols referred to in the explanation in the following outline are shown only as examples, and are not intended to limit the present disclosure to the illustrated modes.

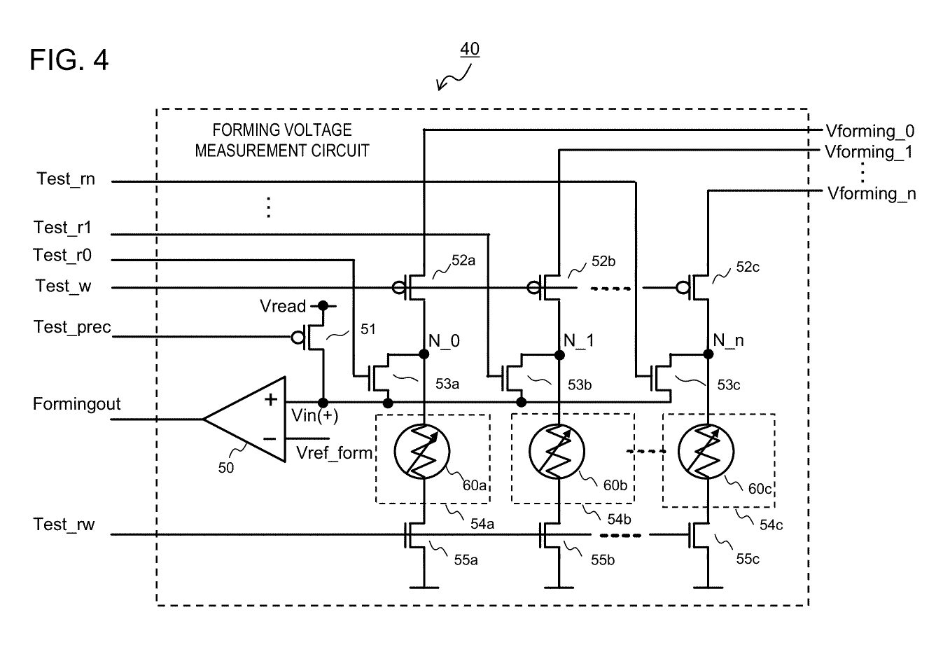

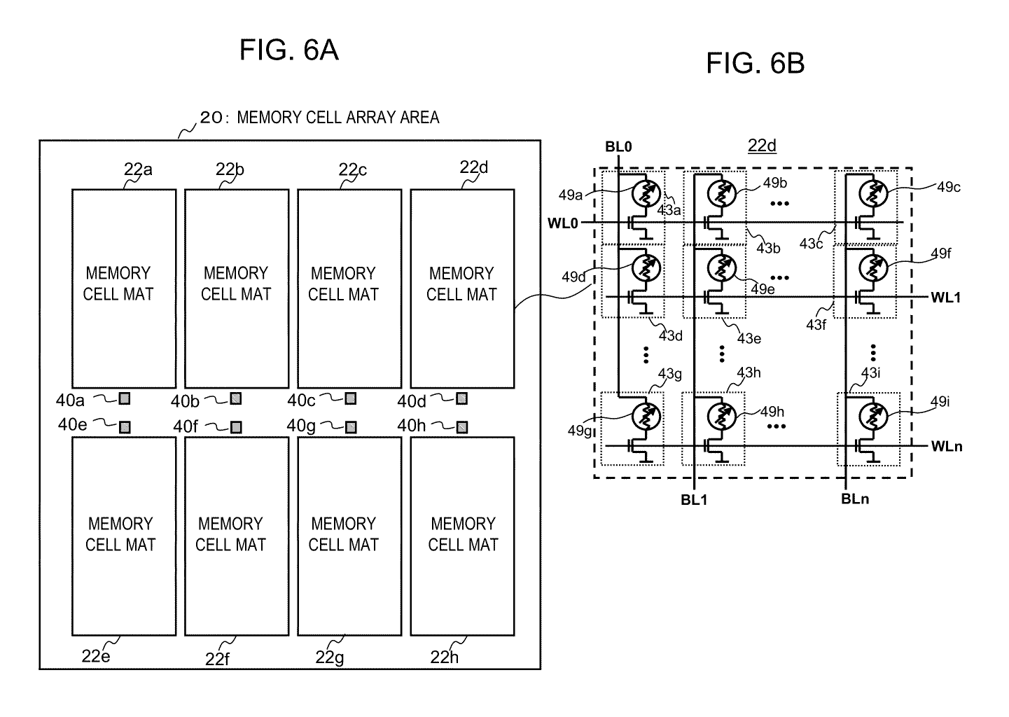

A semiconductor device according to one exemplary embodiment of the present disclosure, as shown in FIG. 4 or FIGS. 6A and 6B, includes a plurality of first memory cells (43a to 43i in FIGS. 6A and 6B) that are accessed at the time of normal operation, wherein the first memory cell includes a first variable resistance element (49a to 49i in FIGS. 6A and 6B); at least one of second memory cells (54a to 54c in FIG. 4) that are not accessed at the time of the normal operation but accessed at the time of test operation, wherein the second memory cell includes a second variable resistance element (60a to 60c in FIG. 4) practically identical to the first variable resistance element; and a control circuit (40 in FIG. 4) that performs a forming on the second memory cell at the time of the test operation.

A method for manufacturing a semiconductor device according to another exemplary embodiment of the present disclosure, as shown in FIG. 4 or FIGS. 6A and 6B, is a method of manufacturing a semiconductor device including a first variable resistance memory cell (43a to 43i in FIGS. 6A and 6B) that operates as a memory at the time of normal operation and a plurality of second variable resistance memory cells (54a to 54c in FIG. 4) that are used for a forming for acquiring forming condition. The method includes: performing a forming control for the plurality of second variable resistance memory cells by different conditions from each other; detecting whether or not each of the plurality of second variable resistance memory cells transits to a first resistance state after the forming control; and performing a forming control for the first variable resistance memory cells based on a condition of one(s) among the plurality of second variable resistance memory cells that transits to the first resistance state as a result of the detection.

Here, the above-mentioned first resistance state is a resistance state of variable resistance memory cell that is obtained after performing a forming under an appropriate forming condition, and after that a reading out, a SET write, and a RESET write can be stably operated.

Exemplary embodiments will be described in detail by referring to the drawings below.

### First Exemplary Embodiment

### Constitution of the First Exemplary Embodiment

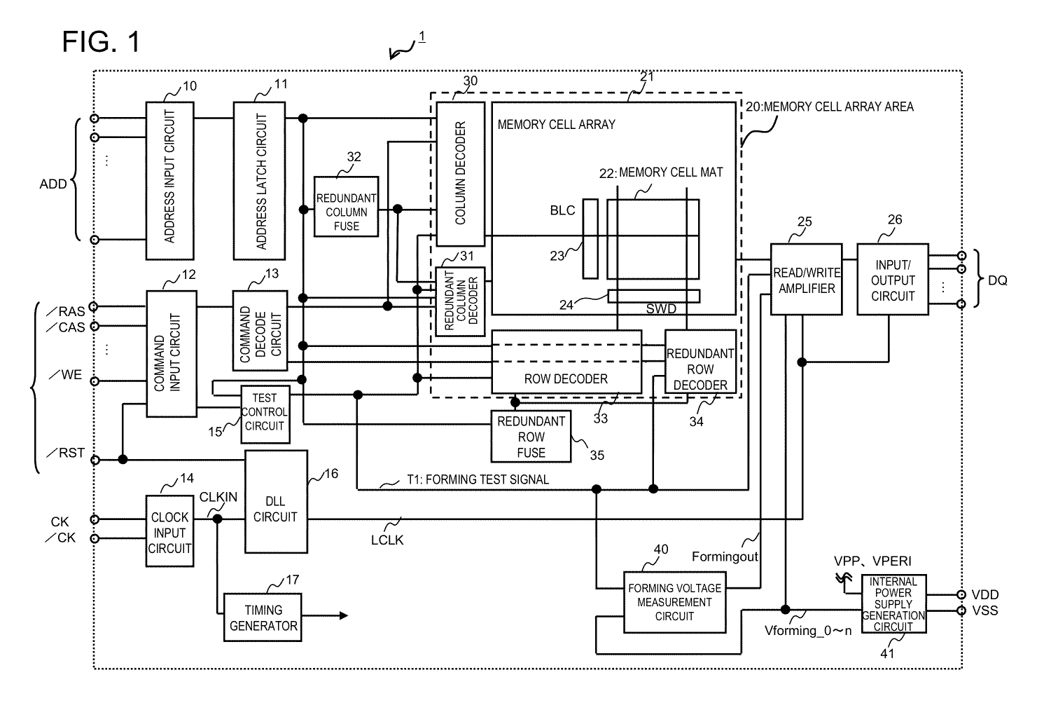

FIG. 1 is a block diagram of an entire semiconductor device in accordance with a first exemplary embodiment of the present disclosure. Memory cells in a semiconductor device 1 include first memory cells (43a to 43i in FIGS. 6A and 6B), and second memory cells (54a to 54c in FIG. 4). Here, the first and second memory cells are memory cells that store information using resistance states, which are also referred to as a first variable resistance memory cell and a second variable resistance memory cell, respectively. And the first memory cell includes a first variable resistance element (49a to 49i in FIGS. 6A and 6B), and the second memory cell includes a second variable resistance element (60a to 60c in FIG. 4) that is practically equivalent to the first variable resistance element.

The first memory cell is a memory cell that performs memory operations of read, SET write, and RESET write at the time of normal operation. In contrast, the second memory cell is a memory cell that is used at the time of test operation such as a forming for acquiring forming condition, and is not accessed at the time of normal operation.

The semiconductor device 1 includes a control circuit 40 that performs a forming for acquiring forming condition on the second memory cells. Here, the above-mentioned control circuit 40 has a function of calculating an optimum forming voltage at the time of the forming for acquiring forming condition, and so the control circuit 40 is hereinafter also referred to as a forming voltage measurement circuit 40. As shown in FIG. 4, the forming voltage measurement circuit 40 is disposed near (adjacently to) the second memory cells (54a to 54c in FIG. 4).

A plurality of memory cell mats (22 in FIG. 1 etc.) are disposed in a memory cell array 21 of FIG. 1. A SWD (Sub Word Driver) 24 driving (sub) word lines and a BLC (Bit Line Controller) 23 controlling bit lines are disposed adjacently to each of the memory cell mats 22.

An address input circuit 10 receives an address ADD of a memory cell that is accessed. Next, an address latch circuit 11 latches the received address ADD, divides the ADD into a row address ADD_row and a column address ADD_column, and supplies the ADD_row and the ADD_column to a row decoder 33 and a column decoder 30 respectively.

The row decoder 33 is a decoder that receives and decodes the row address ADD_row to output a row selection signal. A (sub) word line, which is selected by the above-mentioned row selection signal, becomes active. And the column decoder 30 is a decoder that receives and decodes the column address ADD_column to output a column selection signal. A bit line, which is selected by the above-mentioned column selection signal, becomes active.

A plurality of memory cells in the memory cell mat 22 are two-dimensionally disposed at points of intersection by a plurality of (sub) word lines and a plurality of bit lines. Among the memory cells, a memory cell, which is connected to both the selected (sub) word line and the selected bit line, is selected to be accessed.

A clock input circuit 14 receives external complementary clocks CK, /CK supplied to the semiconductor device 1 from outside to generate an internal clock CLKIN, and supply the internal clock CLKIN to a DLL (Delay Locked Loop) circuit 16 and a timing generator 17. The timing generator 17 generates various timing signals which are needed in the semiconductor device 1 based on the internal clock CLKIN, and supplies the timing signals to each unit. Meanwhile, in the description of the present invention, “/” indicated in the signal name means that the signal is active when the signal is a low level. And the DLL circuit 16 generates a clock signal LCLK from an internal clock CLKIN, and supplies the clock signal LCLK to a read/write amplifier 25 and an input/output circuit 26. In the read/write amplifier 25 and the input/output amplifier 26, a read operation/write operation etc. is performed in synchronization with the supplied clock signal LCLK.

At the time of read operation, the read/write amplifier 25 judges current or voltage of a bit line of a selected memory cell, and outputs data corresponding to the judgment to the input/output circuit 26. And at the time of write operation (SET write or RESET write), the read/write amplifier 25 controls so that an appropriate current flows into a selected memory cell depending on the write data.

At the time of read operation, the input/output circuit 26 receives the data that the read/write amplifier 25 outputs, and converts the data into parallel data, which are outputted from data input/output terminals DQ. At the time of write operation, the input/output circuit 26 converts data that receives in parallel from the data input/output terminals DQ into serial data, and outputs the serial data to the read/write amplifier 25 as data per memory cell.

A command input circuit 12 receives a row address strobe signal /RAS, a column address strobe signal /CAS, a write enable signal /WE, and the like as control signals. A command decoder circuit 13 decodes these signals /RAS, /CAS, /WE, and the like, and outputs control signals, which are needed to execute the decoded command, to each unit in the semiconductor device 1.

A test control circuit 15 receives control signals from the command decode circuit 13 to output a forming test signal T1, which becomes active at the time of forming for acquiring forming condition, to each unit in the semiconductor device 1.

An internal power supply generation circuit 41 receives power supply voltages VDD, VSS that are externally supplied, generates voltages VPP, VPERI, Vforming_0 to Vforming_n that are needed in each unit in the semiconductor device 1, and supplies these voltages to each unit, where Vforming_0 to Vforming_n are (n+1) different forming voltages that are supplied to the forming voltage measurement circuit 40. The (n+1) different forming voltages may be fixed values, or may be varied using command input etc. from outside. It is assumed that these forming voltages satisfy: Vforming_0<Vforming_1< . . . <Vforming_n. That is, these forming voltages are sorted with respect to the magnitude (e.g., in ascending order) of the voltage values.

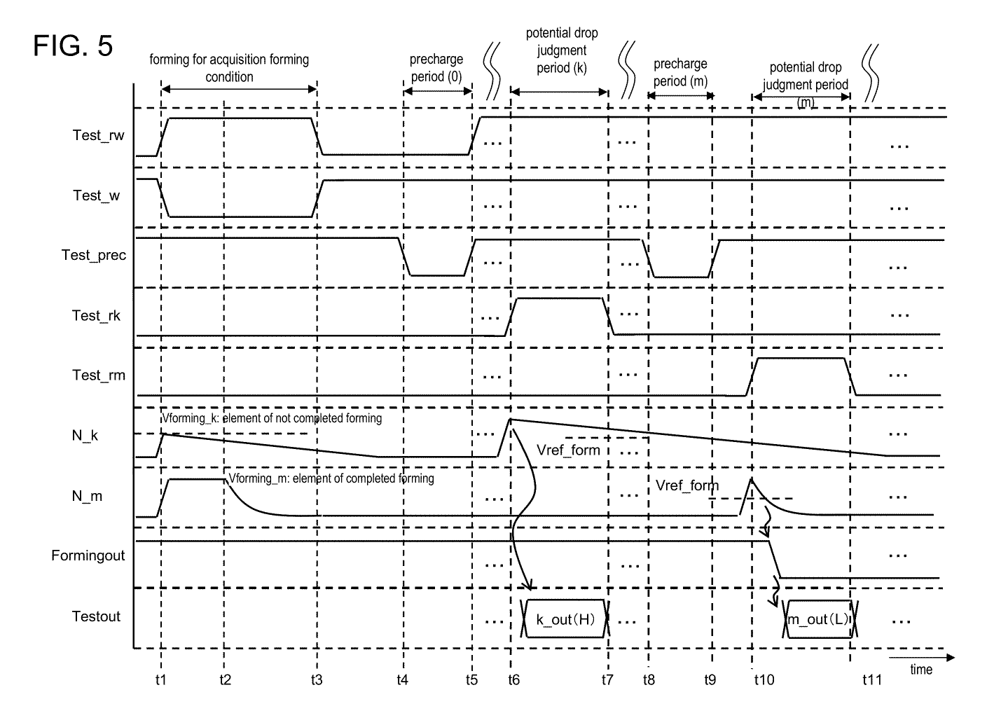

The forming voltage measurement circuit 40 is a circuit for performing a forming for acquiring forming condition. The forming voltage measurement circuit 40 receives the forming test signal T1 from the test control circuit 15, the (n+1) different forming voltages from the internal power supply generation circuit 41 respectively, and outputs Formingout including (n+1) detections of forming conditions to the read/write amplifier 25. The read/write amplifier 25 receives the above-mentioned Formingout including (n+1) detections of forming conditions, converts the (n+1) output voltages in Formingout to data, and outputs the data from the input/output terminals DQ (Testout signal in FIG. 5). Meanwhile, detailed configuration of the forming voltage measurement circuit 40 will be described later when the configuration shown in FIG. 4 will be described.

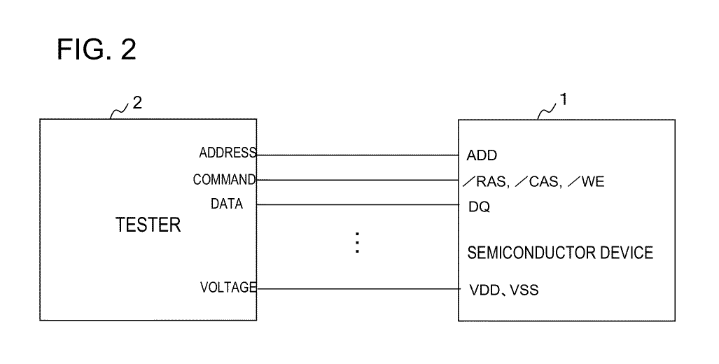

Various tests including a forming for acquiring forming condition in the semiconductor device 1 are performed in a state in which the semiconductor device 1 is connected to a tester 2 as shown in FIG. 2. FIG. 2 shows a connection between the semiconductor 1 and the tester 2. As shown in FIG. 2, terminals of control signals such as /RAS, /CAS, /WE of the semiconductor device 1 are connected to command terminals of the tester 2; data input/output terminals DQ of the semiconductor device 1 are connected to data terminals of the tester 2; and the VDD, VSS terminals of the semiconductor device 1 are connected to voltage terminals of the tester 2. In the connection status mentioned above, various commands are issued from the tester 2 to the semiconductor device 1, and various tests are performed in the semiconductor device 1. And test results (for instance, Testout signal in FIG. 5) are outputted from the data input/output terminals DQ of the semiconductor device 1 to the tester 2 via the data terminals of the tester 2.

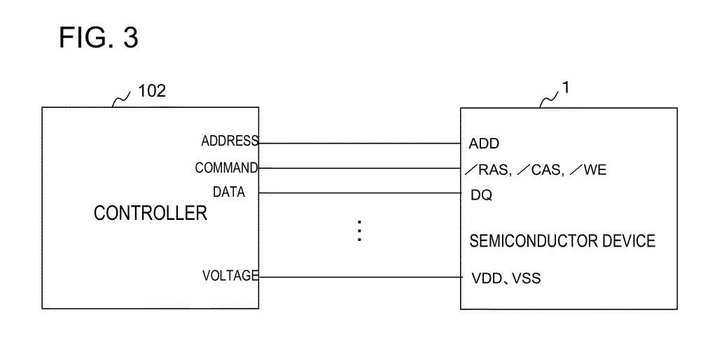

FIG. 3 is a figure showing a connection between the semiconductor device 1 and a controller 102. The controller 102 performs a normal operation (corresponding to a read/write operation, a refresh operation and a power-down operation, etc.) on the semiconductor device 1. During the normal operation, the controller 102 communicates with the memory cell array area 20 and circuits related to the memory cell array area 20 in the semiconductor device 1. On the other hand, the controller 102 does not perform a test operation (including a forming) on the semiconductor device 1. So the controller 102 does not communicate with a test unit including the forming voltage measurement circuit 40 and circuits related to the forming voltage measurement circuit 40 in the semiconductor device 1.

Next, a configuration of the forming voltage measurement circuit 40 will be described in detail by referring to FIG. 4. The forming voltage measurement circuit 40 of FIG. 4 is a circuit having a function in which the (n+1) different forming voltage Vforming_0 to Vforming_n are respectively supplied to (n+1) second memory cells 54a to 54c, and it is detected whether or not each of the forming voltages is appropriate.

The forming voltage measurement circuit 40 includes second memory cells 54a to 54c, PMOS transistors 52a to 52c, NMOS transistors 55a to 55c, NMOS transistors 53a to 53c, a PMOS transistor 51, and a comparator 50.

In FIG. 4, the second memory cells 54a to 54c include second variable resistance elements 60a to 60c respectively. Source/drain of the PMOS transistor 52a is connected in series between one end of the second variable resistance element 60a (node N_0 in FIG. 4) and a wiring supplying the forming voltage Vforming_0. Source/drain of the NMOS transistor 55a is connected between the other end of the second variable resistance element 60a and a ground wiring. The gate of the PMOS transistor 52a is connected to a wiring of control signal Test_w, and the gate of the NMOS transistor 55a is connected to a wiring of control signal Test_rw. The drain of the NMOS transistor 53a is connected to one end of the second variable resistance element 60a (node N_0 in FIG. 4), and the source of the NMOS transistor 53a is connected to a normal input terminal Vin(+) of the comparator 50. The gate of the NMOS transistor 53a is connected to a wiring of control signal Test_r0.

Since connections associated with the other second variable resistance elements (60b to 60c) are similar to the connections associated with the above second variable resistance element 60a, the explanation will be omitted. Control signals Test_r1 and Test_rn are connected to gates of NMOS transistors 53b, 53c, respectively.

The comparator 50 has a function of comparing the potential of a first terminal (normal input terminal; Vin(+) in FIG. 4) with that of a second terminal (reverse input terminal). A voltage of a predetermined reference potential Vref_form is supplied to the reverse input terminal of the comparator 50. A voltage Vread is supplied to the normal input terminal Vin(+) of the comparator 50 via the PMOS transistor 51. Concretely, the source of the PMOS transistor 51 is connected to a wiring of Vread, and the drain of the PMOS transistor 51 is connected to the normal input terminal Vin(+) of the comparator 50. The gate of the PMOS transistor 51 is connected to a wiring of a control signal Test_prec.

From the above connections, relationships between the control signals in FIG. 4 and conductive/non-conductive of the MOS transistors are as follows. First, when the Test_w is low level, the PMOS transistors 52a to 52c are conductive; whereas when the Test_w is high level, the PMOS transistors 52a to 52c are non-conductive. When the Test_rw is high level, the NMOS transistors 55a to 55c are conductive; whereas when the Test_rw is low level, the NMOS transistors 55a to 55c are non-conductive. When one of Test_r0, Test_r1, . . . , Test_rn is high level, the corresponding transistor among the NMOS transistors 53a to 53c is conductive, so that one of the nodes N_0, N_1, . . . , N_n has the same potential as the Vin(+). Namely, since the nodes N_0, N_1, . . . , N_n are connected to one ends of the second memory cells (54a to 54c in FIG. 4) respectively, it occurs that a normal input terminal Vin(+) of the comparator 50 is electrically connected to one of one ends of the second memory cells (54a to 54c in FIG. 4). When Test_r0, Test_r1, . . . , Test_rn are low level, each of the NMOS transistors 53a to 53c are non-conductive, so that the nodes N_0, N_1, . . . , N_n are cut off from the Vin(+), respectively. When the Test_prec is low level, the PMOS transistor 51 is conductive, so that Vin(+) is charged by the power supply Vread; whereas when the Test_prec is high level, the PMOS transistor 51 is non-conductive, so that Vin(+) is cut off from the power supply Vread.

Next, an arrangement of the memory cell array area 20 will be described in detail by referring to FIGS. 6A and 6B. As shown in FIGS. 6A and 6B, the memory cell array area 20 includes a plurality of memory cell mats 22a-h. FIG. 6B shows the detail of one of the memory cell mats (22d). As shown in FIG. 6B, the memory cell mat 22d has a plurality of first memory cells (43a-i in FIGS. 6A and 6B) that are two-dimensionally disposed at points of intersection between bit lines BL0, BL1, . . . , BLn and word lines WL0, WL1, . . . , WLn, and a first memory cell disposed at a point of intersection between the selected bit line and the selected word line is accessed.

In a surrounding circuit area of the memory cell array area 20, the forming voltage measurement circuit 40a-h corresponding to each of the memory cell mats 22a-h is disposed outside each of the memory cell mats 22a-h. Here, each of the forming voltage measurement circuits 40a-h has a configuration as shown in FIG. 4 mentioned above, and is disposed near a plurality of the second memory cells (54a-c in FIG. 4). By using the above configuration, the first memory cells in each of the memory cell mats 22a-h are associated with the second memory cells of the corresponding forming voltage measurement circuit 40a-h (FIG. 6A). At the time of a forming for acquiring forming condition, based on each of the forming voltage measurement circuit 40a-h, a forming condition of the corresponding memory cell mat 22a-h is determined. Detailed method of calculating forming condition will be described later.

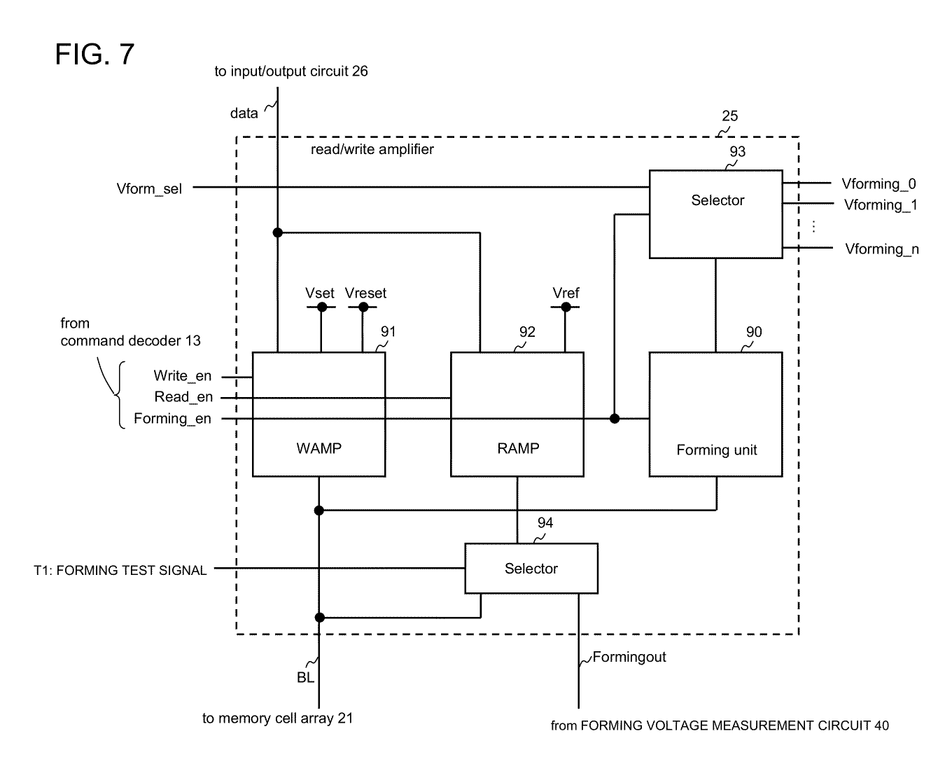

Next, a detailed configuration of the read/write amplifier 25 of FIG. 1 will be described by referring to FIG. 7. As shown in FIG. 7, the read/write amplifier 25 includes a forming unit 90, a write amplifier (WAMP) 91, a read amplifier (RAMP) 92, a selector 93, and a selector 94. And the read/write amplifier 25 has a forming function, a write operation function (including a SET write and a RESET write) at the time of normal operation, and a read operation at the time of normal operation. The forming unit 90, the write amplifier (WAMP) 91, and the read amplifier (RAMP) 92 of FIG. 7 are for a forming, a write operation, and a read operation respectively.

A Forming_en signal, a Write_en signal, and a Read_en signal are respectively supplied to the forming unit 90, the write amplifier (WAMP) 91, and the read amplifier (RAMP) 92 as enable signals. And a Vform_sel signal is supplied to the selector 93 from a test terminal (not shown), and a forming voltage, which has been acquired among (n+1) forming voltages Vforming_0, Vforming_1, . . . , Vforming_n at the time of a forming for acquiring forming condition, is selected by the Vform_sel signal. The selector 94 is a selector that switches between bit lines BL from the memory cell array 21 and the Formingout outputted from the forming voltage measurement circuit 40. Concretely, if during forming for acquiring forming condition, the forming test signal T1 is active, the selector 94 selects the Formingout; in other cases, the selector 94 selects the bit lines BL.

A portion relating to the forming will be described. At the time of forming, the Forming_en signal is active, and a forming voltage that has been acquired at the time of the forming for acquiring forming condition is selected by the Vform_sel signal. The forming unit 90 supplies the forming voltage that that has been acquired at the time of the forming for acquiring forming condition sequentially to each of bit lines of the memory cell array 21, and performs a forming on the first memory cells in the memory cell array 21.

Next, a portion relating to the write operation will be described. In a write operation at the time of normal operation, the write_en signal is active, and the write amplifier (WAMP) 91 operates. Here, if a write data (data signal in FIG. 7) which is supplied from the input/output circuit 26 is “1”, the write amplifier (WAMP) 91 performs a SET write by providing a voltage Vset to a selected variable resistance element through a bit line BL. Whereas, if a write data (data signal in FIG. 7) which is supplied from the input/output circuit 26 is “0”, the write amplifier (WAMP) 91 performs a RESET write by providing a voltage Vreset to a selected variable resistance element through a bit line BL.

Next, a portion relating to the read operation will be described. In a read operation at the time of normal operation, the read_en signal is active, and the read amplifier (RAMP) 92 operates. At this time, since the forming test signal T1 is non-active, the selector 94 selects the bit lines BL. Here, the read amplifier (RAMP) 92 detects a resistance state of a selected variable resistance element by providing a voltage Vref to the selected variable resistance element through a bit line BL, and outputs the detected result to the input/output circuit 26 as a data signal.

Meanwhile, a FIFO (First-In First-Out) circuit (not shown) is provided between the input/output circuit 26 and the write amplifier (WAMP) 91/read amplifier (RAMP) 92, and performs a timing adjustment using a LCLK signal that the DLL circuit 16 outputs.

### Operation of the First Exemplary Embodiment

Next, an operation of the semiconductor device 1 of the present disclosure will be described. In the semiconductor device 1, various operations are performed based on mode settings such as an acquiring forming condition mode, a forming mode, a normal operation mode.

Here, the acquiring forming condition mode is a mode that is performed at the time of manufacturing the semiconductor device 1, in which a forming is performed on a plurality of second memory cells by a plurality of different forming conditions, and forming condition for the first memory cells is determined based on the detection result of the above forming.

And the forming mode is also a mode that is performed at the time of manufacturing the semiconductor device 1, in which a forming is performed on the first memory cells by the forming condition that has been acquired at the above-mentioned acquiring forming condition mode. By performing a forming in the forming mode, the first variable resistance element in the first memory cell becomes a state in which it can be switched between a high resistance state and a low resistance state.

The normal operation mode is a mode in which the first memory cells are used as memory elements, and memory operations including a read, a SET write, and a RESET write are performed in the first memory cells.

Among the above three modes, an operation of the acquiring forming condition mode will be described in detail below.

First, the semiconductor device 1 of FIG. 1 is connected to the tester 2 of FIG. 2, and the tester 2 outputs a setting command of acquiring forming condition mode to the semiconductor device 1. The semiconductor device 1 receives the setting command of acquiring forming condition by the command input circuit 12 and the command decoder circuit 13, so that the semiconductor device 1 becomes the acquiring forming condition mode. If the command decoder circuit 13 informs the test control circuit 15 that the semiconductor device 1 becomes the acquiring forming condition mode, the test control circuit 15 sets the forming test signal T1 to be active. And the test control circuit 15 informs the forming voltage measurement circuit 40, the column decoder 30, the row decoder 33, the read/write amplifier 25, and the like that the forming test signal T1 is active.

When the forming test signal T1 is active, the column decoder 30 and the row decoder 33 are controlled so that both of a column selection signal and a row selection signal are not decoded to be outputted. As the result, the first memory cells in the memory cell array 21 are not selected. When the forming test signal T1 is active, the forming voltage measurement circuit 40 is set to be in an operation state. The internal power supply generation circuit 41 supplies a plurality of different forming voltages Vforming_0 to Vforming_n to the forming voltage measurement circuit 40. Although these voltages are set as fixed voltages in advance in FIG. 1, these voltages may be set by a command from the tester 2. As mentioned above, setting for each unit of acquiring forming condition mode is performed.

Next, an operation of the forming voltage measurement circuit 40 at the time of acquiring forming condition mode will be described by referring to FIGS. 4, 5. The k-th, m-th second memory cells are focused among the (n+1) second memory cells (54a-c) of FIG. 4, and FIG. 5 shows their waveforms (where 0≦k<m≦n). The first to fifth rows of FIG. 5 shows voltage waveforms of the control lines (Test_rw, Test_w, Test_prec, Test_rk, Test_rm) shown in FIG. 4. And the sixth, the seventh rows shows voltage waveforms of nodes N_k, N_m, respectively. The nodes N_k, N_m are nodes which are respectively connected to one ends of the k-th, the m-th second memory cells (nodes similar to the nodes N_0, N_1, N_n shown in FIG. 4). And the eighth row shows an output voltage Formingout of the forming voltage measurement circuit 40 shown in FIG. 4. The read/write amplifier 25 receives the Formingout, and converts the Formingout into (n+1) data; and after that the input/output circuit 26 outputs the (n+1) data as Testout signal to the input/output terminals DQ (FIG. 1). The ninth row (bottom row) shows the Testout signal. More concretely, with reference to FIG. 7, during acquiring forming condition mode, the forming test signal T1 is active, and so the selector 94 selects the Formingout, which is an output of the forming voltage measurement circuit 40, to output the Formingout to the read amplifier (RAMP) 92. The read amplifier (RAMP) 92 converts the Formingout into (n+1) data to output the (n+1) data to the input/output circuit 26.

A period of timing t1 to t3 of FIG. 5 is a period in which a forming is performed on each of the second memory cells 54a-c by a plurality of different forming voltages Vforming_0 to Vforming_n. First, at the timing t1, Test_rw, Test_w signals transit to be active, so that the NMOS transistors 55a-c and the PMOS transistors 52a-c that are connected in series to upper/lower sides of the second memory cells 54a-c become conductive. By the above, a forming for acquiring forming condition gets started on each of the second memory cells 54a-c. A state of filament formation inside each of the second variable resistance elements 60a-c fluctuates depending on unevenness of film thickness of variable resistance elements, an applied forming voltage, or the like. By this fluctuation, there are cases where a forming is not completed, or a forming becomes over-forming. The start timing and gradient of the potential drop at nodes N_k, N_m (0≦k, m≦n) while the forming voltages are applied (period t1 to t3) are influenced by the state inside each of the second variable resistance elements. FIG. 5 shows waveforms in a case where a forming of the k-th second variable resistance element is not completed, and a forming of the m-th second variable resistance element is completed properly. That is to say, as for the (m+1) or more order of second variable resistance elements, as the element order approaches n, the elements tends to be over-forming.

Next, at the timing t3, Test_rw, Test_w signals transit to non-active, so that the NMOS transistors 55a-c and the PMOS transistors 52a-c become non-conductive, and the forming for acquiring forming condition ends. The applied time of forming voltages is t3−t1.

In periods after a timing t4, each of the forming states of the second memory cells, in which the forming for acquiring forming condition has been performed during the period of t1 to t3, is evaluated. The (n+1) second memory cells are evaluated in order. In a case where the i-th second memory cell is evaluated, after the potential of node N_i (one end of the i-th second memory cell) is pre-charged, the forming state of the i-th second memory cell is detected by watching a potential drop when the pre-charged charges are discharged through the second variable resistance element (where i=0, 1, . . . , n). This operation is repeated for i=0, 1, . . . , n. That is to say, the evaluations for the second memory cells includes: a pre-charge period (0) of the 0-th second memory cell, and potential drop judgment period (0) that follows the pre-charge period (0); a pre-charge period (1) of the 1st second memory cell, and potential drop judgment period (1) that follows the pre-charge period (1); . . . ; and a pre-charge period (n) of the n-th second memory cell, and potential drop judgment period (n) that follows the pre-charge period (n). FIG. 5 shows only the pre-charge period (0), the potential drop judgment period (k), the pre-charge period (m), and the potential drop judgment period (m).

An operation after the timing t4 will be described in detail. First, at the timing t4, Test_prec signal transits to be active, so that the PMOS transistor 51 becomes conductive, the pre-charge period (0) starts, and then the potential of the terminal Vin(+) of the comparator 50 is pre-charged to the potential Vread. Next, at the timing t5, Test_prec signal transits to be non-active, so that the PMOS transistor 51 becomes non-conductive, and the pre-charge period (0) ends.

Next, during the pre-charge period (k) that is a period (not shown) just before the timing t6, the potential of the terminal Vin(+) of the comparator 50 is pre-charged to the potential Vread as in the above pre-charge period (0). Next, at the timing t6, Test_rk signal transits to be active. At this timing, since the k-th NMOS transistor (connected to a node N_k) whose gate is connected to the Test_rk signal (not shown, refer to, e.g., Test_rn) becomes conductive so that there is a conductive path between the Vin(+) terminal and the node N_k (one end of the k-th second memory cell), the potential of the node N_k is raised forward the potential of the Vin(+) terminal that has been pre-charged to the potential Vread. Just before the pre-charge, the potential of the node N_k is lowered to the ground level because the Test_rw signal has been kept as an active state. However, the potential of the node N_k is raised forward the potential Vread by the above-mentioned pre-charge. Note that 0≦k≦n holds.

And then, the pre-charged charges are discharged, through the k-th second variable resistance element and the NMOS transistor whose gate is connected to the Test_rw, into the ground, so that the potential of the node N_k (one end of the k-th second memory cell) starts dropping. The gradient of the potential drop at this time depends on the resistance value of the k-th second variable resistance element. If the k-th second variable resistance element has a high resistance, the gradient is small and the charges are discharged slowly; whereas if the k-th second variable resistance element has a low resistance, the gradient is large and the charges are discharged fast. Thus, a potential drop judgment period is determined in advance to be a predetermined period T_judge (in FIG. 5, T_judge=t7−t6=t11−t10), and a potential Vref_form, which the variable resistance element that is in the first resistance state reaches at the end of the period T_judge, is calculated in advance. And as shown in FIG. 4, the reference potential Vref_form is supplied to the reverse input terminal of the comparator 50, it is detected whether or not the potential of the N_k drops to or below the predetermined potential Vref_form during the predetermined period T_judge. By the above, it is possible to be detected whether or not each of the (n+1) second memory cells becomes the first resistance state.

Here, since the k-th second variable resistance element does not become a state in which a forming is completed by the forming for acquiring forming condition and the element has a very high resistance state, the gradient of the potential drop of the node N_k is small. Thus, the potential of the node N_k does not drop to or below the predetermined potential Vref_form by the timing t7. Hence, the Vin(+) terminal of the comparator 50 that is conductive to the node N_k does not drop to or below the predetermined potential Vref_form, so that the comparator 50 outputs a high level, and the Formingout signal becomes a high level.

Next, during the pre-charge period (m) of the timing t8 to t9, the Vin(+) terminal of the comparator 50 is pre-charged to the potential Vread. Since an operation of this period is similar to the pre-charge period (0) and the pre-charge period (k), the explanation will be omitted.

Next, at the timing t10, the Test_rm signal transits to be active. At this timing, since the m-th NMOS transistor whose gate is connected to the Test_rm signal becomes conductive so that there is a conductive path between the Vin(+) terminal and the node N_m (one end of the m-th second memory cell), the potential of the node N_m is raised forward the potential of the Vin(+) terminal that has been pre-charged to the potential Vread. At a timing just before the pre-charge, the potential of the node N_m is in a lowered state to the ground level because the Test_rw signal has been kept as an active. However, the potential of the node N_m is raised forward the potential Vread by the above-mentioned pre-charge.

And the pre-charged charges are discharged, through the second variable resistance element and the NMOS transistor whose gate is connected to the Test_rw, into the ground, so that the potential of the node N_m starts dropping. Here, the m-th second variable resistance element is in a state in which a forming is completed properly by the forming for acquiring forming condition. The resistance value of the m-th second variable resistance element is lower than that in an initial state of the forming, and the gradient of the potential drop of the node N_m is larger than that of the node N_k. The potential of the node N_m drops to or below the predetermined potential Vref_form during the predetermined period T_judge. Hence, since the Vin(+) terminal of the comparator 50 that is conductive to the node N_m drops to or below the predetermined potential Vref_form, and the comparator 50 outputs a low level, the Fromingout signal becomes a low level.

Since forming voltages higher than the m-th forming voltage are supplied to the subsequent m-th second memory cells at the forming for acquiring forming condition, the resistance values of the subsequent m-th second variable resistance elements are less than the resistance value of the m-th second variable resistance element, and the gradients of the potential drop after the pre-charges become further larger. Therefore, the potential of the nodes drops to or below the predetermined potential Vref_form during the predetermined period T_judge, so that the output of the comparator 50 becomes a low level, and the Formingout signal becomes a low level.

The read/write amplifier 25 receives the Formingout, and converts the Formingout into (n+1) data; and after that the input/output circuit 26 outputs the (n+1) data as Testout signal to the input/output terminals DQ (FIG. 1). The ninth row (bottom row) of FIG. 5 shows the Testout signal. Here, the conversion and output of the (n+1) data are executed in synchronization with a clock signal LCLK supplied to the read/write amplifier 25 and the input/output circuit 26 (in FIG. 5, it is shown for convenience that k_out(H), m_out(L) are outputted during t6 to t7, t10 to t11 respectively, but practically they are outputted at different timing(s) from the timing shown in FIG. 5.)

From the above, at a boundary voltage (Vforming_m in FIG. 5) between voltages in which a detection result of forming condition (Formingout in FIG. 5) transits from a high level to a low level, an optimum forming condition which transits from an uncompleted forming state to a completed forming state can be acquired. Thus, it is possible to set the boundary voltage of forming voltages as an optimum forming condition. By transmitting the above Testout signal to the tester 2, it is possible to perform a further arithmetic processing for the detection result at the tester 2 side.

The second memory cell, in which an optimum forming condition has been obtained by the above forming for acquiring forming condition, becomes a first resistance state after the forming. After that, the second memory cell can be operated to stably transit between a first resistance state in which the memory cell becomes a low resistance state by a SET white and a second resistance state in which the memory cell becomes a high resistance state by a RESET write. Here, the resistance value of the first resistance state is lower than that of the second resistance state.

Next, the tester 2 ends the acquiring forming condition mode, and outputs a setting command of forming mode to the semiconductor device 1. The semiconductor device 1 assumes a forming mode by receiving the setting command of forming mode in the command input circuit 12 and command decoder circuit 13 (concretely, the Forming_en of FIG. 7 becomes active by the setting command). If a notification of the transition to forming mode is transmitted from the command decoder circuit 13 to the test control circuit 15, a forming is performed on all the first memory cells using the forming voltage (Vforming_m in the case of FIG. 5) acquired in the forming for acquiring forming condition. Then, the tester 2 ends the forming mode. And the tester 2 is removed from the semiconductor device 1, and after that the semiconductor device 1 starts up as a normal operation mode, and operations of read, SET write, and RESET write are performed.

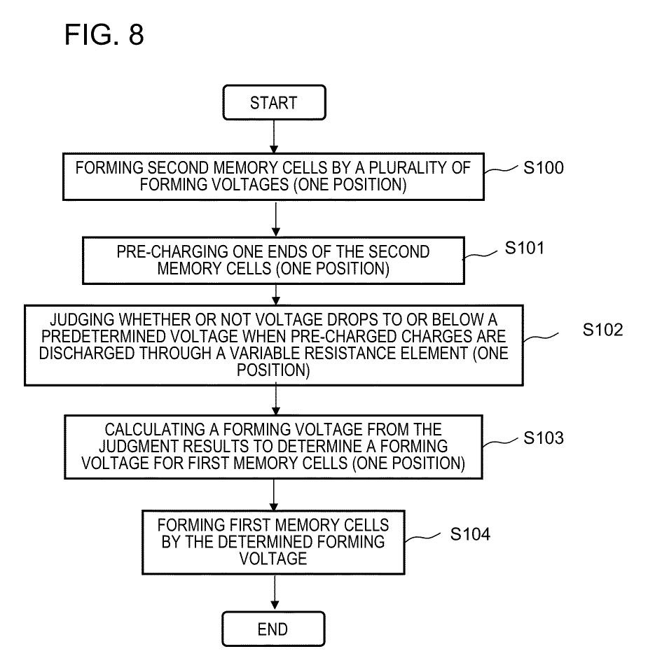

Next, FIG. 8 is a flowchart showing an operation in a case where a forming voltage measurement circuit 40 is disposed only at a single position (e.g., pad) of the memory cell array area 20. The flowchart of FIG. 8 will be explained below, however, repetition of the above explanation in operation with reference to FIGS. 4, 5 may be omitted. First, forming is performed on a plurality of second memory cells using a plurality of different forming voltages (step S100). Next, one ends of the second memory cells (such as N_0, . . . , N_n) are pre-charged (step S101). Concretely, after the Vin(+) terminal of FIG. 4 is pre-charged, one of the NMOS transistors 53a-c is set to be conductive, so that the one end of the second memory cell is raised forward the pre-charged potential. Next, the pre-charged charges are discharged through the second variable resistance element, and it is detected whether or not the potential of the one end(s) of the second memory cell(s) drops to or below the predetermined potential (step S102). Next, an optimum forming voltage is calculated by the detection results. Concretely, a forming voltage at which the detection result for the plurality of different forming voltages transits is set as the optimum forming voltage. Then, a forming voltage for the first memory cells is determined from the above (step S103). Then, a forming is performed on the first memory cells using the determined forming voltage (step S104).

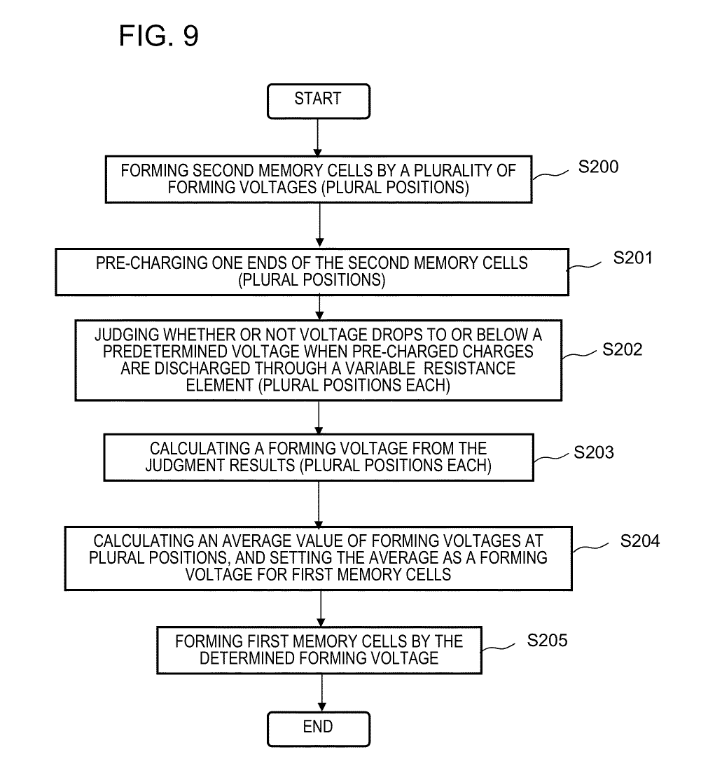

Next, in a case where the second memory cells are disposed by partitioning into a plurality of positions of the memory cell array area 20 as shown in FIGS. 6A and 6B, an operation will be explained. A plurality of forming voltage measurement circuits 40a-h shown in FIGS. 6A and 6B have a configuration of the forming voltage measurement circuit 40 shown in FIG. 4 respectively, and operate as in the forming voltage measurement circuit 40. Here, Testout signals which eight forming voltage measurement circuits 40a-h output are set as Testout_a signal, Testout_b signal, . . . , Testout_h signal respectively. The tester 2 receives the above eight Testout_a-h signals, and calculates a forming voltage for the first memory cell based on the received Testout_a-h signals. Three methods shown in FIGS. 9, 10, and 11 will be described below.

FIG. 9 is a flowchart showing a first method. Step S200 is a step in which the step S100 of FIG. 8 is applied so as to operate in the forming voltage measurement circuits 40a-h of a plurality of positions (eight positions of FIGS. 6A and 6B). And steps S201 to S203 are steps in which steps S101 to S103 of FIG. 8 are applied so as to operate in the forming measurement circuits 40a-h. And in step S203, the tester 2 receives above-mentioned eight Testout_a-h signals. Here, suppose that it can be observed that optimum forming voltages (boundary voltage among forming voltages) are Vforming_a-h respectively by referring to the Testout_a-h signals. Here, the Vforming_a-h are forming voltages at which the second memory cells assume the first resistance state. In step S204, an average value of the forming voltages at the plurality of positions is calculated, and the average value is set as a forming voltage for the first memory cells. Concretely, the average value is calculated by (Vforming_a+Vforming_b+ . . . +Vforming_h)/8. Then, the average value is determined as a forming voltage for the first memory cells, and a forming is performed on all the first memory cells (step S205). According to the first method, the effect is to improve the precision of the forming voltage by averaging the results of the plurality of forming voltage measurement circuits 40a-h, even though there is unevenness in outputs of the forming voltage measurement circuits.

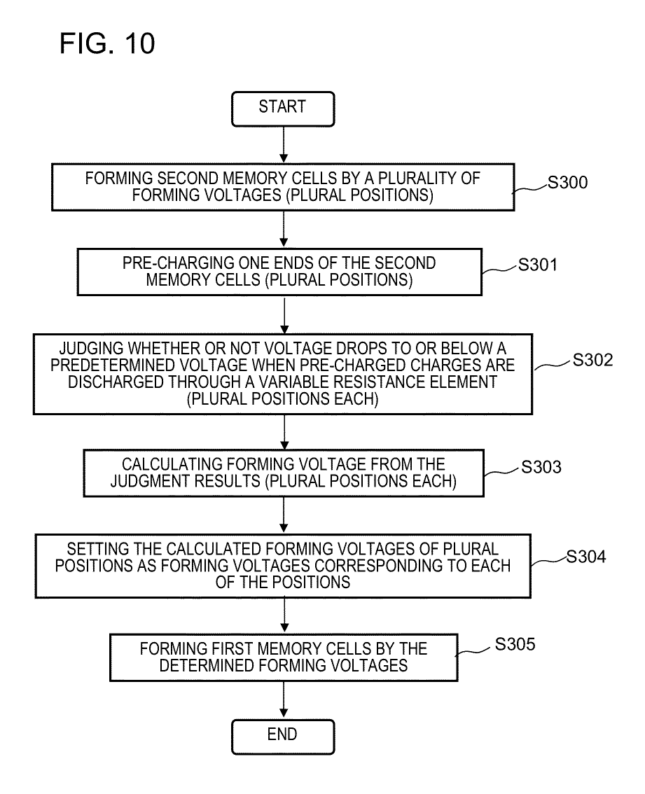

FIG. 10 is a flowchart showing a second method. Since the steps S300, S301 and S303 are the same as the steps S200, S201 and S202 of FIG. 9 respectively, the explanations will be omitted. In step S304, forming voltages, that are calculated at each of the positions (boundary voltage among forming voltages), are set as forming voltages for the first memory cells corresponding to each of the positions. Concretely, forming voltages for the first memory cells in each of the memory cell mats shown in FIGS. 6A and 6B are set by forming voltages calculated by the forming voltage measurement circuits corresponding to each of the memory cell mats. That is, forming voltages for the first memory cells in the memory cell mats 22a-h are set to be Vforming_a-h respectively. Here, the Vforming_a-h are forming voltages in which the second memory cells assume the first resistance state. And forming is performed on the first memory cells using the forming voltage determined for each of the memory cell mats (step S305). According to the second method, even though there is unevenness of characteristics among variable resistance elements in a chip, the effect is to solve the problem of the unevenness and calculate an optimum forming condition by calculating forming voltage depending on each of the positions.

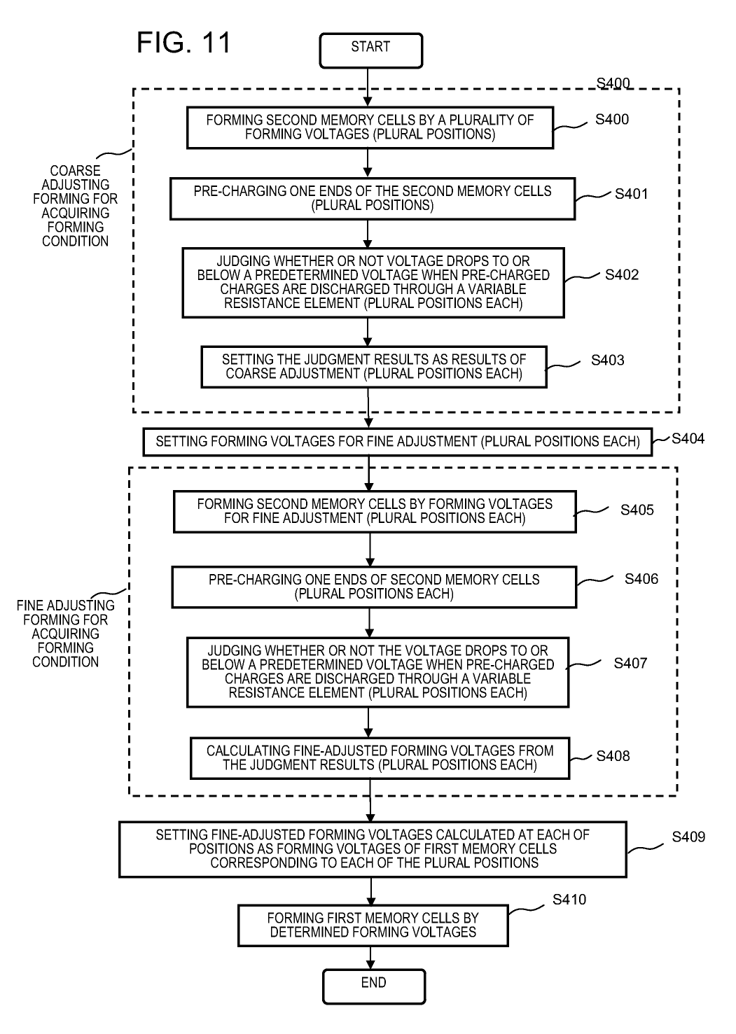

FIG. 11 is a flowchart showing a third method. As shown in FIG. 11, a forming for acquiring forming condition is performed by two stages including a coarse adjusting forming for acquiring forming condition and a fine adjusting forming for acquiring forming condition. In this case, two sets of forming voltage measurement circuits 40a-h are needed as a coarse (rough) adjustment and a fine adjustment. And two sets of forming voltage measurement circuits are provided at each of the positions. In FIG. 11, since steps S400, S401, S402 and S403 of the coarse adjustment are the same as the steps S200, S201, S202 and S203 of FIG. 9 respectively, the explanations will be omitted. Here, in S403, forming voltages (boundary voltage among forming voltages) calculated at the plurality of positions are set as coarse adjustment results.

And then, the tester 2 respectively sets forming voltages of fine adjustment of the second stage at the positions (e.g., mats) based on the results of the coarse adjustment of forming voltages at the plurality of positions mentioned above (e.g., eight positions in FIGS. 6A and 6B). For example, it is assumed that step size of forming voltage is 0.2 V in the coarse adjustment and a boundary forming voltage is calculated as 2.0 V. In the fine adjustment, a forming in which the range is 1.8 V to 2.2 V and the step size is 0.1 V is set. The settings of fine adjusting forming voltage are transmitted as a command from the tester 2, and the forming voltages Vforming_0 to Vforming_n of FIG. 4 are modified.

And fine adjustment forming voltages are calculated at each of the positions by steps S405 to S408 for the second memory cells of fine adjusting forming adjustment circuits of each of the positions. Since operations of the steps S405 to S408 are the same as the steps S400 to S403 of the coarse adjustment respectively, the explanations will be omitted. And in step S409, forming voltages (boundary voltage among forming voltages) that have been finely adjusted at each of the positions are set as forming voltages for the first memory cells corresponding to each of the positions. The step S409 is the same as the step 304. And then, in step S410, forming is performed on every memory cell mat of the first memory cells using the forming voltages determined for each of the memory cell mats. The step S410 is the same as the step S305. According to the third method, the effect is to calculate a forming condition with a higher precision by dividing into two stages of the coarse adjustment and the fine adjustment.

As explained above, according to the semiconductor device in accordance with the first exemplary embodiment, since the memory cells (second memory cells) used for forming for acquiring forming condition are provided separately other than the first memory cells operating as memories at the time of normal operation, the effect is to provide a semiconductor device in which defective cells due to the forming for acquiring forming condition are not produced in the first memory cells.

Even though the forming condition fluctuates due to unevenness of the film thickness of the variable resistance elements, the effect is to calculate always an optimum forming condition by a forming for acquiring forming condition, and perform a forming on the first memory cells. And a circuit required for the forming for acquiring forming condition can be easily provided in the semiconductor integrated circuit as shown in FIG. 4, which makes it possible to realize a cost reduction and size reduction of the chip.

### Second Exemplary Embodiment

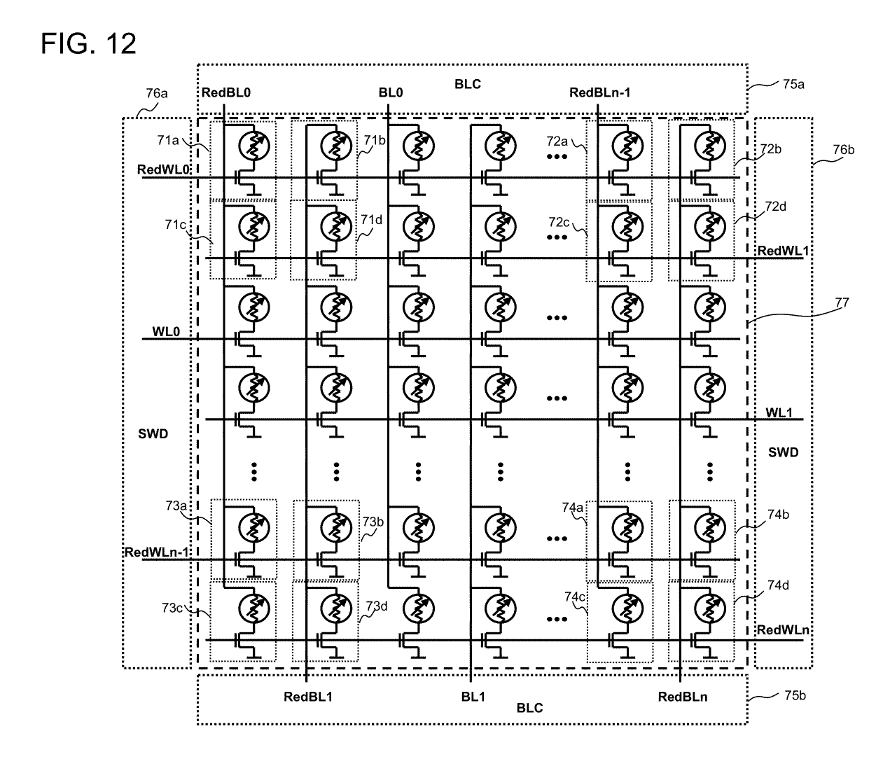

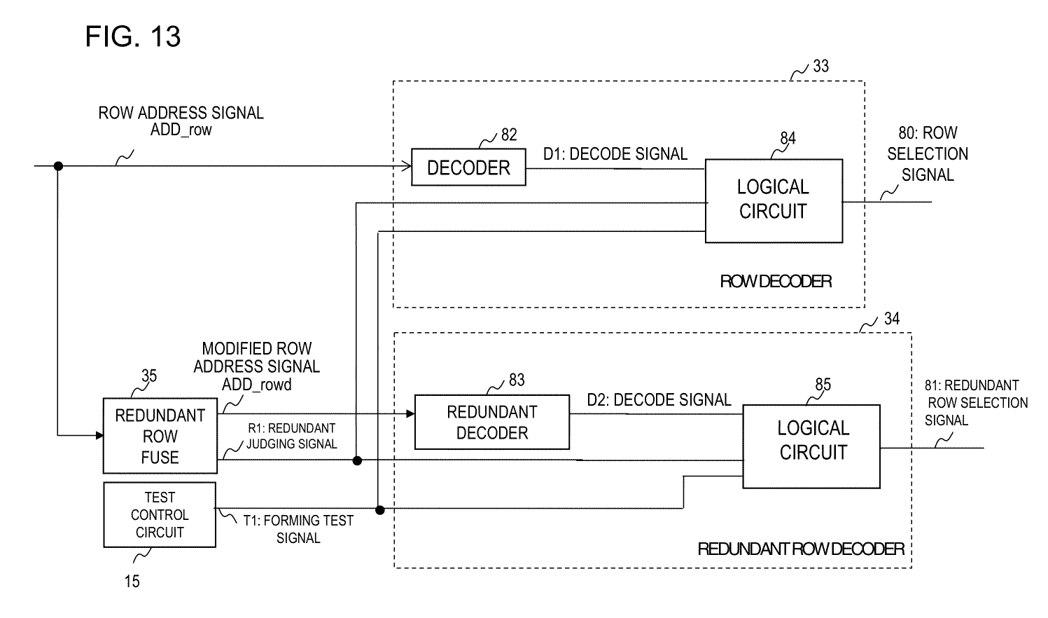

In a second exemplary embodiment, the semiconductor device 1 includes redundant memory cells to rescue a memory, and is constituted so that the second memory cells used for a forming for acquiring forming condition are selected from the above redundant memory cells. FIG. 1 is a block diagram showing an overview of the semiconductor device in accordance with both of the first and second exemplary embodiments. A difference of the second exemplary embodiment from the first exemplary embodiment is illustrated in FIGS. 12, 13 concretely (the details are described later). Since a memory rescue by redundant memory cells is a publicly known method, the first exemplary embodiment may be also constituted so that the memory rescue by redundant memory cells is performed.

A semiconductor device 1 in accordance with the second exemplar embodiment shown in FIG. 1 further includes a redundant column decoder 31, a redundant column fuse 32, a redundant row decoder 34, and a redundant row fuse 35. And the memory cell array 21 has a plurality of redundant memory cells in its inside. In an inspection step after manufacturing the memory cell array 21, if defects of memory cells inside the memory cell array 21 are detected and it is determined that the defects can be substituted by redundant memory cells, a memory rescue is executed by the following substitution. According to this, the effect is to improve a yield rate of the memory cell array 21. On the other hand, if it is determined that defects cannot be repaired by substitution of redundant memories, the memory cell array 21 is treated as a defective product.

When a defective cell is substituted by redundant memories, in order that address of the defective portion indicates an address in redundant memories, electric fuses in the redundant column fuse 32 and the redundant row fuse 35 are cut off. The cutting off the electric fuses of the redundant column fuse 32 and the redundant row fuse 35 mentioned above is performed in the inspection step at the time of manufacturing.

FIG. 12 shows an example of memory cell arrangement of the semiconductor device 1 in accordance with the second exemplary embodiment, and shows a memory cell mat 77 in the memory cell array 21, and BLCs (Bit Line Controller) 75a, 75b, and SWDs (Sub Word Driver) 76a, 76b disposed adjacently to the memory cell mat 77. The BLCs (75a, 75b) control bit lines BL0, BL1, and redundant bit lines RedBL0, RedBL1, RedBLn−1, RedBLn. And the SWDs (76a, 76b) control (sub) word lines WL0, WL1, and redundant (sub) word lines RedWL0, RedWL1, RedWLn−1, RedWLn. Here, memory cells connected to the redundant word lines or the redundant bit lines are redundant memory cells. In the second exemplary embodiment, memory cells disposed at four corners of the memory cell mat 77 from memory cells connected to redundant lines (in FIG. 12, redundant bit lines RedBL0, RedBL1, RedBLn−1, RedBLn; redundant (sub) word lines RedWL0, RedWL1, RedWLn−1, RedWLn) disposed at peripheral portions among these redundant memory cells are selected as the second memory cell used for forming for acquiring forming condition. If it is assumed that four memory cells are used at each of the positions, 71a-d, 72a-d, 73a-d, 74a-d shown in FIG. 12 are the second memory cells that are selected at each of the positions. However, number of selected memory cells is arbitrary, and is not limited to four. The forming voltage measurement circuits 40 shown in FIG. 4 are provided at each of the positions as in the first exemplary embodiment. Since the second memory cell circuits are provided inside the memory cell mat 77 as mentioned above, the forming voltage measurement circuits (40a-h of FIGS. 6A and 6B or the like) disposed outside the memory cell mat as shown in FIGS. 6A and 6B of the first exemplary embodiment are unnecessary. Thus, a difference of the second exemplary embodiment from the first exemplary embodiment resides in that the second memory cells are selected from redundant memory cells in the second exemplary embodiment.

And the second memory cells in which forming for acquiring forming condition has been performed, if not in an over-forming state, the second memory cells can be also used for redundant memory cells for rescue of defective cells. However, for the second memory cells in which forming voltage has been not applied sufficiently, it is necessary to calculate shortage amount of the forming voltage, and apply the voltage corresponding to the shortage to compensate. On the other hand, the second memory cells, which become over-forming than a calculated forming condition by a forming for acquiring forming condition, are treated as defective cells, and are set so as to be not accessed as redundant memory cells for rescue of defective cells.

Next, FIG. 13 is a detailed block diagram of the row decoder and the redundant row decoder in accordance with the second exemplary embodiment. A row address signal ADD_row that the address latch circuit 11 outputs is supplied to the row decoder 33 and the redundant row fuse 35. If the redundant row fuse 35 judges that the received row address signal ADD_row is an address in which the memory cell of the ADD_row is substituted by a redundant memory cell, the redundant row fuse 35 sets a redundant judging signal R1 to be active, and outputs a modified row address signal ADD_rowd indicating the substitution destination. The test control circuit 15 sets the forming test signal T1 to be active at the time of an acquiring forming condition mode. And a decoder 82 inside the row decoder 33 receives a row address signal ADD_row to output a decode signal D1. A redundant decoder 83 inside the redundant row decoder 34 receives a modified row address signal ADD_rowd to output a decode signal D2.

A logical circuit 84 inside the row decoder 33 receives the decode signal D1, the redundant judging signal R1, and the forming test signal T1 to output a row selection signal 80. Here, the logical circuit 84 executes the following logical operation. When R1 or T1 is “H” (high level), the output of the logical circuit 84 is “L” (low level; non-selected); when R1 is “L” and T1 is “L”, the output of the logical circuit 84 is the decode signal D1.

On the other hand, the logical circuit 85 inside the redundant row decoder 34 receives the decode signal D2, the redundant judging signal R1, and the forming test signal T1 to output a redundant row selection signal 81. Here, the logical circuit 85 executes the following logical operation.

When T1 is “H”, the output of the logical circuit 85 is “H” (selected);
when T1 is “L” and R1 is “H”, the output of the logical circuit 85 is the decode signal D2; and
when T1 is “L” and R1 is “L”, the output of the logical circuit 85 is “L” (non-selected).

By these logical operations of logical circuits 84, 85, if the forming test signal T1 is “H” at the time of an acquiring forming condition mode, the row selection signal 80 is “L” (non-selected) and the redundant row selection signal 81 is “H” (selected), so that all the redundant memory cells are selected. However, since only certain redundant memory cells that are selected as the second memory cells among the redundant memory cells are connected to control signals Test_w and Test_rw (see FIG. 4), the only redundant memory cells that are selected as the second memory cell (71a-d, 72a-d, 73a-d, 74a-d of FIG. 12 or the like) among the redundant memory cells are accessed at the time of forming for acquiring forming condition.

If T1 is “L”, that is, a memory operation is performed at the time of normal operation, an operation similar to the conventional rescue function by redundant memory cells is performed by the above-mentioned logical operations of the logical circuits 84, 85.

Meanwhile, FIG. 13 is a figure relating to row addresses, in contrast, a constitution for column addresses is obtained by substituting the column address signal ADD_column for the row address signal ADD_row, and substituting the column decoder 30, the redundant column decoder 31, and redundant column fuse 32 for the row decoder 33, the redundant row decoder 34, and the redundant row fuse 35 respectively in FIG. 13. Since these operations are similar to those relating to row address, the explanation will be omitted.

In a case where the second memory cells are disposed by dividing into a plurality of positions of the memory cell array 21, methods shown in the flowcharts of FIGS. 9 to 11 can be also applied in the second exemplary embodiment as shown in the first exemplary embodiment. Here, a case where a forming for acquiring forming condition is performed for arrangement of the second memory cells shown in FIG. 12 will be explained as an example. It is assumed that forming voltages calculated by forming voltage measurement circuits disposed at four corners of the memory cell mat 77 shown in FIG. 12 are Vforming_71, Vforming_72, Vforming_73, and Vforming_74 respectively. Here, an average value of these four forming voltages may be set as a forming voltage for the first memory cells of the whole area of the memory cell mat 77. The area of the memory cell mat 77 may be divided into a left upper part, a right upper part, a left lower part, and a right lower part, and the forming voltage corresponding to each of the parts (one of Vforming_71 to Vforming_74) may be set as a forming voltage for the first memory cell of each of the parts. Alternatively, an average value of forming voltages obtained from forming voltage measurement circuits of a plurality of the memory cell mats including the memory cell array 21 may be set as a forming voltage for all the first memory cells in the memory cell array 21. As mentioned above, it is possible to calculate a forming voltage(s) for the first memory cells by executing various types of arithmetic processing for the forming voltages that are calculated by the second memory cells disposed at the plurality of positions.

Characteristics of variable resistance elements tend to be different between a far end and a near end of (sub) word lines and bit lines inside the memory cell mat 77. In such a case, the effect is to acquire forming voltages reflecting the characteristics by disposing the forming voltage measurement circuits 40 at the four corners of the memory cell mat 77, and compensate the unevenness between the far end and the near end of (sub) word lines and bit lines.

As explained above, in the semiconductor device 1 in accordance with the second exemplary embodiment, the second memory cells used for a forming for acquiring forming condition are selected from the redundant memory cells. Defective cells that are produced in the forming for acquiring forming condition are set not to be used for substituting for a defective cell as redundant memory cells. According to this, the effect is to provide a semiconductor device in which defective cells due to a forming for acquiring forming condition are not produced for the memory cells that operates as a memory cell at the time of normal operation.

Meanwhile, in the first and second exemplary embodiments, a case where only the forming voltage is used as a parameter is explained. However, the parameter is not limited to the forming voltage. For example, by constituting so that forming time (t3−t1 of FIG. 5) can be adjusted, forming condition may be adjusted by the forming time. Alternatively, forming voltage is constituted as pulse voltage, and forming condition may be adjusted by number of applied pulses. Alternatively, a plurality of the above adjustable parameters may be combined. Of course, in any cases, the effects that are mentioned in each of the exemplary embodiments can be obtained.

The present disclosure can be applied to a non-volatile semiconductor memory device that has a variable resistance element as a memory element. In particular, the present invention is preferably applied in a case where a forming for acquiring forming condition of a variable resistance element is performed at the step of manufacturing the non-volatile semiconductor memory device.

The exemplary embodiments and examples may include variations and modifications without departing the gist and scope of the present invention as disclosed herein and claimed as appended herewith, and furthermore based on the fundamental technical spirit. It should be noted that any combination and/or selection of the disclosed elements may fall within the claims of the present invention. That is, it should be noted that the present invention of course includes various variations and modifications that could be made by those skilled in the art according to the overall disclosures including claims and technical spirit.

What is claimed is:

1. A semiconductor device comprising:
a plurality of first memory cells that are accessed during normal operation, wherein each of the first memory cells includes a first variable resistance element;
at least one second memory cell that is not accessed during said normal operation but accessed at a time of test operation, wherein said at least one second memory cell includes a second variable resistance element practically identical to said first variable resistance element; and
a control circuit that performs forming on said at least one second memory cell at the time of said test operation.

2. The semiconductor device according to claim 1, wherein
said plurality of first memory cells constitute a plurality of memory cell mats; and
said at least one second memory cell is disposed outside said plurality of memory cell mats.

3. The semiconductor device according to claim 1, wherein
said control circuit, after said forming, further performs pre-charging to one end of said at least one second memory cell by a predetermined potential, and detects a potential drop when charges of said pre-charging are discharged through said second variable resistance element.

4. The semiconductor device according to claim 2, wherein
said control circuit, after said forming, further performs pre-charging to one end of said at least one second memory cell by a predetermined potential, and detects a potential drop when charges of said pre-charging are discharged through said second variable resistance element.

5. The semiconductor device according to claim 3, wherein
said control circuit is disposed near said at least one second memory cell.

6. The semiconductor device according to claim 4, wherein
said control circuit is disposed near said at least one second memory cell.

7. The semiconductor device according to claim 3, wherein
said control circuit comprises a comparator that compares a potential of a first terminal with that of a second terminal;
said first terminal is connected to one end of said at least one second memory cell; and
a predetermined reference potential is supplied to said second terminal.

8. The semiconductor device according to claim 4, wherein
said control circuit comprises a comparator that compares a potential of a first terminal with that of a second terminal;
said first terminal is connected to one end of said at least one second memory cell; and
a predetermined reference potential is supplied to said second terminal.

9. The semiconductor device according to claim 1, including a plurality of said second memory cells, wherein
said control circuit, by applying a plurality of different forming voltages to each of said plurality of second memory cells, performs forming by applying said plurality of different forming voltages;
said control circuit detects a boundary voltage of said forming voltages that reverses an output of said comparator among said plurality of different forming voltages; and
said control circuit determines a forming voltage for said first memory cells based on the detected boundary voltage.

10. A method of manufacturing a semiconductor device, wherein said semiconductor device includes first variable resistance memory cells that operate as a memory during normal operation and a plurality of second variable resistance memory cells that are used for a forming for acquiring forming condition, said method comprising:
performing a forming control for said plurality of second variable resistance memory cells by different conditions from each other;
detecting whether or not each of said plurality of second variable resistance memory cells transits to a first resistance state after said forming control; and
performing a forming control for said first variable resistance memory cells based on a condition of one(s) among said plurality of second variable resistance memory cells that transits to said first resistance state as a result of said detection.

11. The method of manufacturing a semiconductor device according to claim 10, wherein
it is detected whether or not each of said plurality of second variable resistance memory cells transits to said first resistance state by performing controls for said plurality of second variable resistance memory cells one by one, said controls comprising:
a control of pre-charging one end of said second variable resistance memory cell;
a control of discharging said one end through the second variable resistance memory cell itself after the pre-charging; and
a control of comparing the discharged potential with a reference potential.

12. The method of manufacturing a semiconductor device according to claim 10, wherein
after said forming control, said each of plurality of second variable resistance memory cells transits to either of said first resistance state or second resistance state, wherein said first resistance state is lower in resistance than said second resistance state.

13. The method of manufacturing a semiconductor device according to claim 10, wherein
a forming control is performed on said first variable resistance memory cells based on an average of conditions of said plurality of second variable resistance memory cells that transit to said first resistance state among said plurality of second variable resistance memory cells.

14. The method of manufacturing a semiconductor device according to claim 11, wherein
a forming control is performed on said first variable resistance memory cells based on an average of conditions of said plurality of second variable resistance memory cells that transit to said first resistance state among said plurality of second variable resistance memory cells.

15. The method of manufacturing a semiconductor device according to claim 12, wherein
a forming control is performed on said first variable resistance memory cells based on an average of conditions of said plurality of second variable resistance memory cells that transit to said first resistance state among said plurality of second variable resistance memory cells.

16. A system, comprising:
a semiconductor device that includes:
a first memory circuit including a plurality of normal and redundancy memory cells each including a variable resistance element;
a second memory circuit including at least one test memory cell including the variable resistance element; and
a controller coupled to said semiconductor device, said controller being configured to perform a read/write operation on said first memory circuit of said semiconductor device and not to perform the read/write operation on said second memory circuit.

17. The system according to claim 16, wherein said semiconductor device further includes a command decode circuit coupled to said first memory circuit and a test control circuit coupled to said second memory circuit, said controller being configured to activate said command decode circuit to perform the read/write operation on said first memory circuit and inactivate said test control circuit not to perform the read/write operation on said second memory circuit.

18. The system according to claim 17, wherein said semiconductor device further includes an address circuit coupled to said first memory circuit, said controller supplying said address circuit with address information to select one or more normal and redundancy memory cells on which the read/write operation is performed, said address circuit being uncoupled from said second memory circuit.

19. The system according to claim 16, wherein said semiconductor device further includes an internal power supply generation circuit supplying a first internal voltage to said first memory circuit and not to said second memory circuit, supplying a second internal voltage to said second memory circuit and not to said first memory circuit.
